(19) United States
(12) Patent Application Publication
(10) Pub. No.: US 2025/0309025 A1
(43) Pub. Date: Oct. 2, 2025

(54) ON-DIE HEATING FOR A MEMORY DEVICE

(71) Applicant: Micron Technology, Inc., Boise, ID (US)

(72) Inventors: Natalia Tarazona Cordoba, Munich (DE); Ken Choong Lim, Munich (DE); Jun Tan, Weißenfeld (DE)

(21) Appl. No.: 19/080,731

(22) Filed: Mar. 14, 2025

Related U.S. Application Data
(60) Provisional application No. 63/570,641, filed on Mar. 27, 2024.

(51) Int. Cl. H01L 23/34; G05D 23/19; H10N 70/00

(52) U.S. Cl. CPC H01L 23/345; G05D 23/1917; H01L 23/34; H10N 70/861; H10N 70/883

(57) ABSTRACT

Methods, systems, and devices for on-die heating for a memory device are described. A system may monitor a temperature associated with a memory die that includes a set of heating blocks. The set of heating blocks may heat the memory die and generate an activation signal based on the temperature associated with the memory die satisfying one or more thresholds. Further, the system may activate one or more heating blocks of the set of heating blocks based on the activation signal. In some examples, activating the one or more heating blocks may provide for an adjustment of the temperature associated with the memory die.

### CROSS REFERENCE

The present Application for Patent claims priority to U.S. Patent Application No. 63/570,641 by Tarazona Cordoba et al., entitled “ON-DIE HEATING FOR A MEMORY DEVICE,” filed Mar. 27, 2024, which is assigned to the assignee hereof, and which is expressly incorporated by reference in its entirety herein.

### TECHNICAL FIELD

The following relates to one or more systems for memory, including on-die heating for a memory device.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports on-die heating for a memory device in accordance with examples as disclosed herein.

FIG. 2A shows an example of a system that supports on-die heating for a memory device in accordance with examples as disclosed herein.

FIG. 2B shows an example of a graph that supports on-die heating for a memory device in accordance with examples as disclosed herein.

FIG. 3 shows an example of a circuit that supports on-die heating for a memory device in accordance with examples as disclosed herein.

FIG. 4 shows a block diagram of a system that supports on-die heating for a memory device in accordance with examples as disclosed herein.

FIG. 5 shows a flowchart illustrating a method or methods that support on-die heating for a memory device in accordance with examples as disclosed herein.

### DETAILED DESCRIPTION

Components of a memory system, such as one or more memory dice, may undergo stress testing during manufacturing to ensure that the components are relatively reliable and durable in the field. During stress testing, a component, or more specifically a memory die, may be placed on a burn-in board (BIB) (e.g., a printed circuit board (PCB) that is used during stress testing) which may be placed in an oven tester. Using the oven tester, one or more memory dice may be heated to a target temperature (e.g., a temperature that simulates wear and tear over time). However, in some examples, the oven tester may not be configured to provide even temperature distribution over the BIB and various dice on the BIB may have temperatures that vary substantially. For example, a temperature difference between memory dice on the BIB may range from 10 degrees Celsius to 20 degrees Celsius, among other example temperature ranges. As a result, a first portion of the memory dice of the BIB may reach the target temperature while a second portion of the memory dice of the BIB may not (e.g., under stressed memory dice). To compensate, a temperature of the oven tester may be increased so a first portion of the memory dice of the BIB may reach the target temperature while a second portion of the memory dice of the BIB may far exceed the target temperature causing other challenges. However, increasing the temperature of the oven tester may cause some of the memory dice in the second portion to exceed the target temperature (e.g., over stressed memory dice) and may potentially result in memory die damage, BIB damage, oven tester damage, melted socket balls, or an increase in stress testing time, among other challenges.

On-die heaters, however, may provide even heat distribution across the BIB or compensate for the temperature distribution of the oven tester. In some examples, an on-die heater may be coupled with a memory die (e.g., a memory die on the BIB) and include or otherwise be associated with a temperature sensor, one or more controllers, and a set of heating blocks. The temperature sensor may sense a temperature (e.g., a junction temperature) associated with the memory die and signal the temperature to the one or more controllers. Based on (e.g., after, at the same time as, in response to) receiving the temperature, the one or more controllers may compare the temperature to a threshold. As an example, the threshold may be equal to or less than the target temperature.

If the temperature is below the threshold, the one or more controllers may generate an activation signal to activate at least a subset of the set of heating blocks and transmit the activation signal to the set of heating blocks. In response to the activation signal, the subset of heating blocks may activate or remain in an activated state. After activation or while in the activated stated, each heating block of the subset may dissipate heat to a respective array region of the memory die. Alternatively, if the temperature is above or equal to the threshold, the one or more controllers may generate a deactivation signal to deactivate the subset of heating blocks and transmit the deactivation signal to the set of heating blocks. In response to the deactivation signal, the subset of heating blocks may deactivate or remain in a deactivated state. After deactivation or while in the deactivated stated, each heating block of the subset may not dissipate heat.

Additionally, or alternatively, the one or more controllers may compare the temperature to one or more thresholds, and each threshold of the one or more thresholds may correspond to a respective heating level (e.g., an amount of power dissipated from a singular heating block). If the temperature satisfies a temperature threshold corresponding to a heating level, the one or more controllers may include an indication of the heating level in the activation signal and the subset of heating blocks may dissipate heat in accordance with the heating level. That is, the on-die heater may vary its strength in response to the temperature of the memory die. Unlike other methods, the on-die heaters may regulate the heat supplied to each individual die allowing each memory die to reach the target temperature. If used in conjunction with the oven tester, the on-die heaters may reduce damage to BIB components or oven tester components because increasing the temperature of the oven heater to compensate for under stressed memory dice may no longer be needed.

In addition to applicability in memory systems as described herein, techniques for on-die heating for a memory device may be generally implemented to improve the sustainability of various electronic devices and systems. As the use of electronic devices has become even more widespread, the amount of energy used, and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by enhancing testing and component endurance over time, which may extend the life of electronic devices and reduce electronic waste, among other benefits.

Features of the disclosure are illustrated and described in the context of systems and architectures. Features of the disclosure are further illustrated and described in the context of a graph and flowcharts.

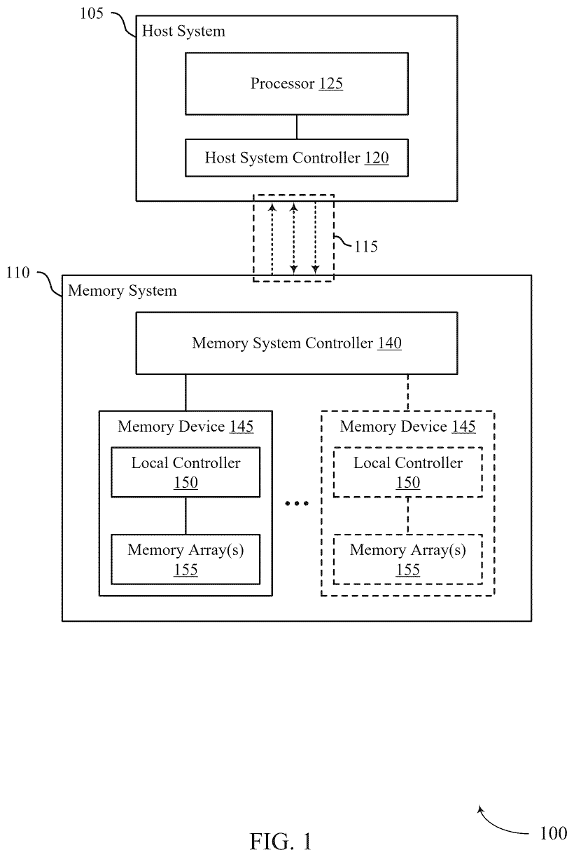

FIG. 1 illustrates an example of a system 100 that supports on-die heating for a memory device in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dice, memory chips) operable to store data. The memory system 110 may be configurable for operations with different types of host systems 105 and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, a heater may be located on at least one of the memory devices 145 of the memory system 110. The heater may include a temperature sensor configured to sense a temperature of the memory device 145. Further, the heater may include one or more controllers coupled with the temperature sensor and one or more heating blocks. The one or more controllers may be configured to generate an activation signal based on the temperature sensed by the temperature sensor and transmit the activation signal to the one or more heating blocks. In response to the activation signal, the one or more heating blocks may dissipate heat to one or more array regions of the memory device 145. That is, the heater may regulate (or increase) the temperature of the memory device 145 such that the temperature of the memory device 145 is within a threshold value of a target temperature (e.g., a stress testing temperature for manufacturing processes).

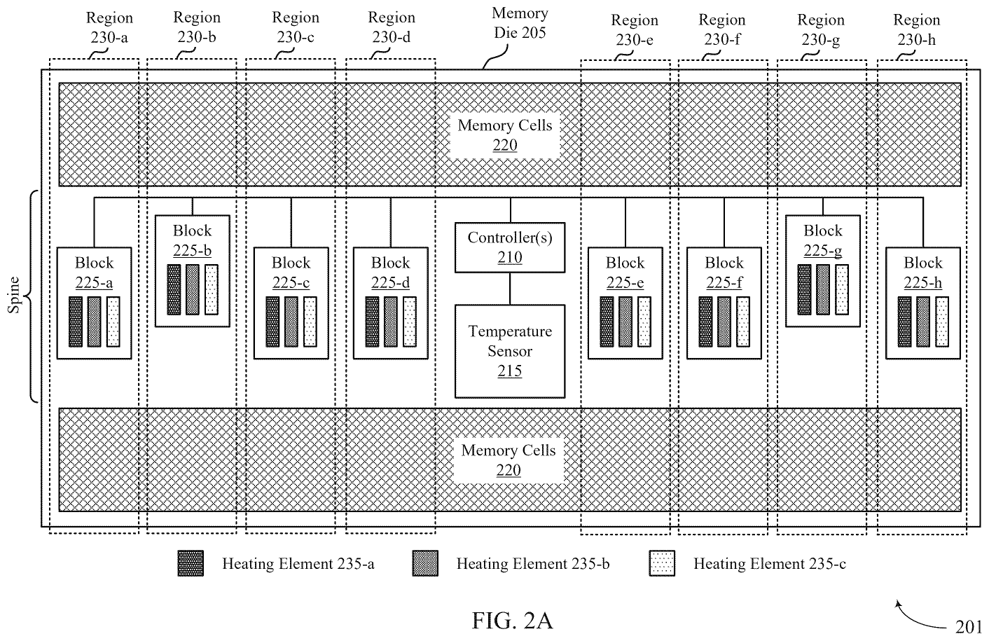

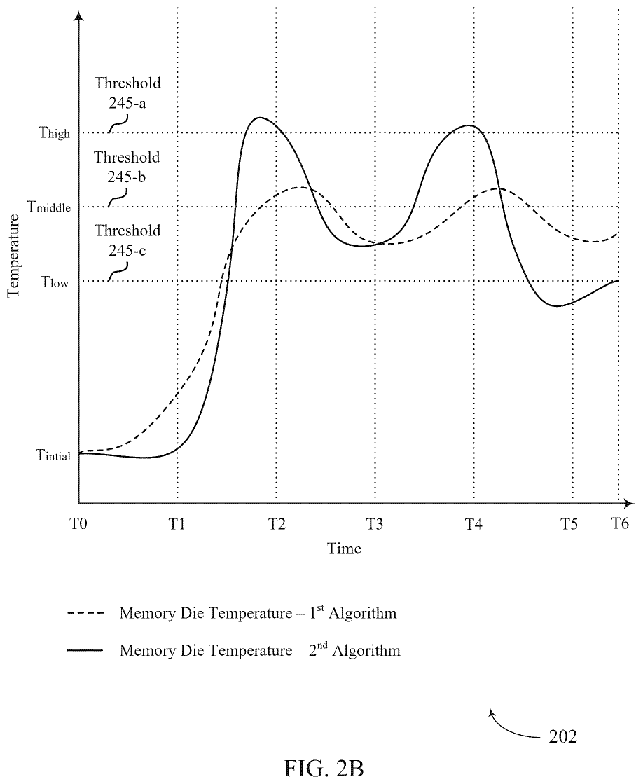

FIG. 2A illustrates an example of a system 201 that supports on-die heating for a memory device in accordance with examples as disclosed herein. In some examples, the system 201 may implement aspects of a system 100. For example, the system 201 may include a memory die 205 which may be an example of a memory device 145 as described with reference to FIG. 1

FIG. 2B illustrate an example of graph 202 that supports on-die heating for a memory device in accordance with examples as disclosed herein. In some examples, aspects of the graph 202 may be implemented by aspects of the system 100. For example, aspects of the graph 202 may be implemented by a memory device 145 as described with reference to FIG. 1.

In some examples, the memory die 205 may include memory cells 220 divided into one or more memory portions. As shown in FIG. 2A, the memory cells 220 of the memory die 205 may be divided into two memory portions (e.g., a top memory portion and a bottom memory portion, or some other portions). The memory portions may be separated by a space known as a spine of the memory die 205. The spine may include circuitry to support functionality of the memory die 205. In some examples, each memory portion may include multiple banks of memory cells 220. For example, each of the two memory portions may include four bank groups and each bank group may include four banks of memory cells 220.

During manufacturing, the memory die 205 may undergo stress testing to detect failures due to defects. As part of the stress testing, the memory die 205 may be heated to a target temperature. In order to heat the memory die 205 to the target temperature, the memory die 205 may include a heater that includes components such as a temperature sensor 215, one or more controllers 210, and a set of heating blocks 225 (e.g., a heating block 225-a, a heating block 225-b, a heating block 225-c, a heating block 225-d, a heating block 225-e, a heating block 225-f, a heating block 225-g, and a heating block 225-h). In some examples, the temperature sensor 215 may be coupled with the one or more controllers 210 and the one or more controllers 210 may be coupled with the set of heating blocks 225.

As shown in FIG. 2A, the components of the heater may be located on the spine of the memory die 205 (or may be integrated with the circuitry of the spine). In some examples, the set of heating blocks 225 may be distributed across the spine such that a distance (e.g., a horizontal distance) between each consecutive heating block 225 of the set is equal. Further, in some examples, the set of heating blocks 225 may be located along a center line of the spine or situated equidistance between the memory portions. As another option and as shown in FIG. 2A, a first subset of the set of heating blocks 225 (e.g., the heating block 225-a, the heating block 225-c, the heating block 225-d, the heating block 225-e, the heating block 225-f, and the heating block 225-h) may be located along the center line of the spine while a second subset of the set of heating blocks 225 (e.g., the heating block 225-b and the heating block 225-g) may be vertically offset from the center line of the spine.

In some examples, the heating blocks 225 may be divided into two groups: a first group of heating blocks 225 (e.g., the heating block 225-a, the heating block 225-b, the heating blocks 225-c, and the heating block 225-d) and a second group (e.g., the heating block 225-e, the heating block 225-f, the heating blocks 225-g, and the heating block 225-h). As shown in FIG. 2A, the first group of heating blocks 225 may occupy a left half of the memory die 205 (e.g., a first channel of the memory die) and the second group of heating blocks 225 may occupy a right half of memory die 205 (e.g., a second channel of the memory die).

The one or more controllers 210 and the temperature sensor 215 may also be located on the spine. In some examples, the one or more controllers 210 and the temperature sensor 215 may be centrally located on the spine. For example, the one or more controllers 210 and the temperature sensor 215 may be situated between the two groups of heating blocks 225. Although FIG. 2A illustrates the components of the heater (e.g., the one or more controllers 210, the temperature sensor 215, and the set of heating blocks 225) at particular locations on the spine of the memory die 205, it is understood that the components of the heater may be at locations on the memory die 205 different from those illustrated in FIG. 2A.

During stress testing, the heater may be operable to heat the memory die 205 using the set of heating blocks 225 based on a temperature of the memory die 205 monitored by the temperature sensor 215. In some examples, each heating block 225 may correspond to a different region 230 of the memory die 205. For example, the heating block 225-a, the heating block 225-b, the heating block 225-c, the heating block 225-d, the heating block 225-e, the heating block 225-f, the heating block 225-g, and the heating block 225-h may corresponds to a region 230-a, a region 230-b, a region 230-c, a region 230-d, a region 230-e, a region 230-f, a region 230-g, and a region 230-h, respectively. Each region 230 may cover at least a percentage of a memory portion (e.g., one or more banks) of the memory die 205. When in an activated state, a heating block 225 may be configured to dissipate heat to its respective region 230. Alternatively, when in a deactivated state, the heating block 225 may be configured to not dissipate heat to its respective region 230.

In some examples, each of the heating blocks 225 of the set may include a quantity of heating elements 235 (e.g., a heating element 235-a, a heating element 235-b, and a heating element 235-c). Each heating element 235 of a heating block 225 may be enabled or disabled. If a heating element 235 is enabled and the heating block 225 including the heating element 235 is in an activated state, the heating element 235 may emit power to heat the respective region 230. Alternatively, if the heating element 235 is disabled and the heating block 225 including the heating element 235 is in an activated state, the heating element 235 may not emit power.

In some examples, a quantity of enabled heating elements 235 included in a heating block 225 may represent a heating level for the heating block 225. For example, one enabled heating element 235 (e.g., the heating element 235-a) may represent a first heating level, two enabled heating elements 235 (e.g., the heating element 235-a and the heating element 235-b) may represent a second heating level, and three enabled heating elements 235 (e.g., the heating element 235-a, the heating element 235-b, and the heating element 235-c) may represent a third heating level. The more heating elements 235 that are enabled for the heating block 225, the higher the heating level is for the heating block 225 (e.g., the greater the power dissipated to the region 230 corresponding to the heating block 225).

In some examples, the heater may implement a first algorithm or a second algorithm to dynamically heat the memory die 205. Using a first algorithm, the heating level of the heating blocks 225 may be set prior to stress testing (e.g., via a test mode) and the heater may update an operating state of the heating blocks 225 (e.g., from the activated state to the deactivated state or vice versa) based on a temperature of the memory die 205 satisfying a threshold. Using a second algorithm, the heater may heat the memory die 205 by dynamically updating the heating level of the heating blocks 225 based on the temperature of the memory die 205 satisfying one or more thresholds.

FIG. 2B illustrates a temperature of the memory die 205 during stress testing. T0 may represent a start of the stress testing and T6 may represent an end of the stress testing. From T0 to T6, the temperature sensor 215 may monitor the temperature of the memory die 205 and report the temperature of the memory die 205 to the one or more controllers 210 at different time points (e.g., T1, T2, T3, T4, and T5). In some examples, the temperature sensor 215 may report the temperature of the memory die 205 in a periodic or aperiodic manner.

The following describes one or more actions performed by the heater during stress testing while operating according to the first algorithm.

In some examples, prior to T0, the heating level of the heating blocks 225 may be set. For example, the heating blocks 225 may set to the second heating level (e.g., the heating elements 235-a and the heating element 235-b are enabled). At T0, the heating blocks 225 may be in the deactivated state and the temperature sensor 215 may sense that a temperature of the memory die 205 is equal to an initial temperature (or Tᵢₙᵢₜᵢₐₗ).

At T1, the temperature sensor 215 may transmit a signal to the one or more controllers 210 indicating the temperature at T1 (or a first temperature). In response to the signal, the one or more controllers 210 may compare the first temperature to a threshold 245-b (or T_{middle}). The threshold 245-b may be equal to the target temperature or may be less than the target temperature. The one or more controllers 210 may determine that the first temperature is below the threshold 245-b and generate an activation signal to activate the set of heating blocks 225. The one or more controllers 210 may transmit the activation signal to the one or more heating blocks 225 and in response to the activation signal, the set of heating blocks 225 may switch from the deactivated state to the activated state. In the activated state, the set of heating blocks 225 may dissipate heat (e.g., in accordance with the second heating level).

At T2, the temperature sensor 215 may transmit a signal to the one or more controllers 210 indicating the temperature at T2 (or a second temperature). In response to the signal, the one or more controllers 210 may compare the second temperature to the threshold 245-b. The one or more controllers 210 may determine that the second temperature is above the threshold 245-b and generate a deactivation signal to deactivate the set of heating blocks 225. The one or more controllers 210 may transmit the deactivation signal to the one or more heating blocks 225 and in response to the deactivation signal, the set of heating blocks 225 may switch from the activated state to the deactivated state.

At T3, the temperature sensor 215 may transmit a signal to the one or more controllers 210 indicating the temperature at T3 (or a third temperature). In response to the signal, the one or more controllers 210 may compare the third temperature to the threshold 245-b. The one or more controllers 210 may determine that the third temperature is below the threshold 245-b and generate the activation signal to activate the set of heating blocks 225. The one or more controllers 210 may transmit the activation signal to the one or more heating blocks 225 and in response to the activation signal, the set of heating blocks 225 may switch from the deactivated state to an activated state. In the activated state, the set of heating blocks 225 may dissipate heat (e.g., in accordance with the second heating level).

At T4, the temperature sensor 215 may transmit a signal to the one or more controllers 210 indicating the temperature at T4 (or a fourth temperature). In response to the signal, the one or more controllers 210 may compare the fourth temperature to the threshold 245-b. The one or more controllers 210 may determine that the fourth temperature is above the threshold 245-b and generate a deactivation signal to deactivate the set of heating blocks 225. The one or more controllers 210 may transmit the deactivation signal to the one or more heating blocks 225. In response to the deactivation signal, the set of heating blocks 225 may switch from the activated state to the deactivated state.

At T5, the temperature sensor 215 may transmit a signal to the one or more controllers 210 indicating the temperature at T5 (or a fifth temperature). In response to the signal, the one or more controllers 210 may compare the fifth temperature to the threshold 245-b. The one or more controllers 210 may determine that the fifth temperature is below the threshold 245-b and generate the activation signal to activate the set of heating blocks 225. The one or more controllers 210 may transmit the activation signal to the one or more heating blocks 225 and in response to the activation signal, the set of heating blocks 225 may switch from the deactivated state to the activated state. In the activated state, the set of heating blocks 225 may dissipate heat (e.g., in accordance with the second heating level).

That is, using the first algorithm, the heater may deactivate the set of heating blocks 225 when the temperature exceeds the threshold 245-b and activate the set of heating blocks 225 when the temperature is below the threshold 245-b.

Alternatively, the heater may implement the second algorithm. The following describes one or more actions performed by the heater while operating in accordance with the second algorithm.

At T0, the heating blocks 225 may be in the deactivated state and the temperature sensor 215 may sense that the temperature of the memory die 205 is equal to the initial temperature (or Tᵢₙᵢₜᵢₐₗ).

At T1, the temperature sensor 215 may transmit a signal to the one or more controllers 210 indicating the temperature at T1 (or a sixth temperature). In response to the signal, the one or more controllers 210 may compare the sixth temperature to a threshold 245-a (or T_{high}), the threshold 245-b (or T_{middle}), and a threshold 245-c (or T_{low}). In some examples, the threshold 245-a may be greater than the target temperature and the threshold 245-c may be less than the target temperature. The one or more controllers 210 may determine that the sixth temperature is below the threshold 245-c and generate the activation signal to activate the set of heating blocks 225. Additionally, the one or more controllers 210 may select the third heating level (e.g., default heating level) and include an indication of the third heating level in the activation signal. The one or more controllers 210 may transmit the activation signal to the one or more heating blocks 225 and in response to the activation signal, the set of heating blocks 225 may switch from the deactivated state to the activated state. In the activated state, the set of heating blocks 225 may dissipate heat (e.g., in accordance with the third heating level).

At T2, the temperature sensor 215 may transmit a signal to the one or more controllers 210 indicating the temperature at T2 (or a seventh temperature). In response to the signal, the one or more controllers 210 may compare the seventh temperature to the threshold 245-a, the threshold 245-b, and the threshold 245-c. The one or more controllers 210 may determine that the seventh temperature is above the threshold 245-a and generate the activation signal to activate the set of heating blocks 225. Additionally, the one or more controllers 210 may select the second heating level (or any heating level below the third heating level) and include an indication of the second heating level in the activation signal. The one or more controllers 210 may transmit the activation signal to the one or more heating blocks 225 and in response to the activation signal, the set of heating blocks 225 may remain active and dissipate heat (e.g., in accordance with the second heating level).

At T3, the temperature sensor 215 may transmit a signal to the one or more controllers 210 indicating the temperature at T3 (or an eighth temperature). In response to the signal, the one or more controllers 210 may compare the eighth temperature to the threshold 245-a, the threshold 245-b, and the threshold 245-c. The one or more controllers 210 may determine that the eighth temperature is below the threshold 245-a and above the threshold 245-c and generate the activation signal to activate the set of heating blocks 225. Additionally, the one or more controllers 210 may select the second heating level (or the same heating level as selected at T2) and include an indication of the second heating level in the activation signal. The one or more controllers 210 may transmit the activation signal to the one or more heating blocks 225 and in response to the activation signal, the set of heating blocks 225 may remain active and dissipate heat (e.g., in accordance with the second heating level).

At T4, the temperature sensor 215 may transmit a signal to the one or more controllers 210 indicating the temperature at T4 (or a ninth temperature). In response to the signal, the one or more controllers 210 may compare the ninth temperature to the threshold 245-a, the threshold 245-b, and the threshold 245-c. The one or more controllers 210 may determine that the ninth temperature is above the threshold 245-a and generate the activation signal to activate the set of heating blocks 225. Additionally, the one or more controllers 210 may select the first heating level (or any heating level below the second heating level) and include an indication of the first heating level in the activation signal. The one or more controllers 210 may transmit the activation signal to the one or more heating blocks 225 and in response to the activation signal, the set of heating blocks 225 may remain active and dissipate heat (e.g., in accordance with the first heating level).

At T5, the temperature sensor 215 may transmit a signal to the one or more controllers 210 indicating the temperature at T5 (or a tenth temperature). In response to the signal, the one or more controllers 210 may compare the tenth temperature to the threshold 245-b, the threshold 245-b, and the threshold 245-c. The one or more controllers 210 may determine that the tenth temperature is below the threshold 245-c and generate the activation signal to activate the set of heating blocks 225. Additionally, the one or more controllers 210 may select the second heating level (or any heating level above the first heating level) and include an indication of the second heating level in the activation signal. The one or more controllers 210 may transmit the activation signal to the one or more heating blocks 225 and in response to the activation signal, the set of heating blocks 225 may remain active and dissipate heat (e.g., in accordance with the second heating level).

That is, the heater may increase the heating level when the temperature is below the threshold 245-c, maintain the heating level when the temperature falls between the threshold 245-c and the threshold 245-a, and decrease the heating level when the temperature exceeds the threshold 245-a.

In some examples, the activation signal may include a set of bits whose logic values indicate the heating level selected by the one or more controllers 210. For example, the activation signal may include a first bit, a second bit, and a third bit corresponding to the heating element 235-a, the heating element 235-b, and the heating element 235-c, respectively. A logic value of 1 may indicate that the corresponding heating element 235 is enabled while a logic value of 0 may indicate that the corresponding heating element 235 is disabled. Thus, 110 may indicate the second heating level in which the heating elements 235-a and the heating element 235-b is enabled. In some examples, each heating element 235 may include digital gates (or local logic) that may allow the heating block 225 to disable or enable the heating elements 235 of the heating block 225 in response to the activation signal.

In some examples, prior to T0, at least a subset of the set of heating blocks 225 may be disabled. For example, the heating block 225-c and the heating block 225-d may be disabled while the remaining heating blocks 225 are enabled. If a heating block 225 is disabled, the heating block 225 may not enter the activated state in response to the activation signal and may remain in the deactivated state throughout stress testing. Alternatively, the heater may dynamically enable or disable the heating blocks 225 based on the temperature of the memory die 205. For example, in response to the temperature satisfying one or more of the thresholds 245, the one or more controllers 210 may select one or more heating blocks 225 to disable and include an indication of the one or more heating blocks 225 to disable within the activation signal or another signal. Additionally, or alternatively, each heating block 225 may be coupled with its own local temperature sensor that is configured to sense a temperature at or around the respective heating block 225. In such examples, the heater may enable or disable the heating blocks 225 based on the temperature sensed by the local temperature sensors.

The on-die heater may regulate the temperature of the memory die 205 such that the temperature of the memory die 205 is within a threshold value of the target temperature during stress testing. Implementing on-die heaters during stress testing may reduce a temperature deviation of a burn-in board (BIB) caused by an oven tester during stress testing.

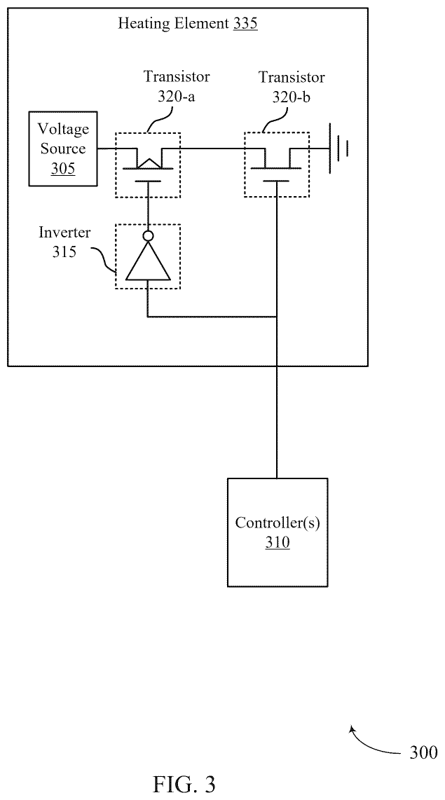

FIG. 3 shows an example of a circuit 300 that supports on-die heating for a memory device in accordance with examples as disclosed herein. In some examples, the circuit 300 may be implemented by aspects of the system 100 and the system 201. For example, the circuit 300 may be implemented in a memory device 145 as described with reference to FIG. 1. Additionally, the circuit 300 may implemented by a heating element 235 as described with reference to FIG. 2A.

In some examples, a heater may be located on a memory die and may include a temperature sensor, one or more controllers 310, and a set of heating blocks. A heating block of the set of heating blocks may be operable to dissipate heat to an array region of the memory die using one or more heating elements 335. In order to dissipate heat, each heating element 335 of the heating block may include a transistor 320-a (e.g., a positive metal-oxide semiconductor (PMOS) transistor), a transistor 320-b (e.g., a negative metal-oxide semiconductor (NMOS) transistor), an inverter 315, and a voltage source 305 (or V_{dd}).

A first node (or source) of the transistor 320-a may be coupled with the voltage source 305, a second node (or drain) of the transistor 320-a may be coupled with a first node (or source) of the transistor 320-b, and a third node (or gate) of the transistor 320-a may be coupled with a first node (or output) of the inverter 315. Further, a second node (or drain) of the transistor 320-b may be coupled with ground (or Vₛₛ) and a third node (or gate) of the transistor 320-b may be coupled with the one or more controllers 310. Additionally, a second node (or input) of the inverter 315 may be coupled with the one or more controllers 310.

As described with reference to FIGS. 2A and 2B, the one or more controllers 310 may generate an activation signal in response to a temperature of the memory die satisfying one or more thresholds. For example, the one or more controllers 310 may generate an activation signal in response to the temperature of the memory die falling below a target temperature. Based on (e.g., after, at the same time as, in response to) generating the activation signal, the one or more controllers 310 may transmit the activation signal to the set of heating blocks that includes the one or more heating elements 335.

If a heating element 335 of the one or more heating elements 335 is enabled, the activation signal may flow to the third node of the transistor 320-b and switch the transistor 320-b from an off state to an on state. Further, the activation signal may flow to the first node of the inverter 315. The inverter 315 may invert the activation signal and output the inverted activation signal to the third node of the transistor 320-a such that the transistor 320-a switches from an off state to an on state. While in the on state, the transistor 320-a and the transistor 320-b may form a conductive pathway between the voltage source 305 and ground. Along the conductive pathway, current may flow from voltage source 305 through the transistor 320-a and the transistor 320-b to ground. As the current flows from the voltage source 305 to ground, power, in the form of heat, may dissipate to the array region of the memory die corresponding to the heating block. In some examples, a size of the transistors 320 may be based on a target power dissipation for heating.

At a later time, the one or more controllers 310 may generate a deactivation signal in response to a temperature of the memory die satisfying the one or more thresholds. For example, the one or more controllers 310 may generate a deactivation signal in response to the temperature of the memory die rising above the target temperature. Based on (e.g., after, at the same time as, in response to) generating the deactivation signal, the one or more controllers 310 may transmit the deactivation signal to the set of heating blocks that includes the one or more heating elements 335.

If a heating element 335 of the one or more heating elements 335 is enabled, the deactivation signal may flow to the third node of the transistor 320-b and switch the transistor 320-b from the on state to the off state. Further, the deactivation signal may flow to the second node of the inverter 315. The inverter 315 may invert the deactivation signal and output the inverted deactivation signal to the third node of the transistor 320-a such that the transistor 320-a switches from the on state to the off state. While in the off state, the transistor 320-a and the transistor 320-b may disconnect the voltage source 305 from ground such that current no longer flows from the voltage source 305 to ground and power, in the form of heat, no longer dissipates to the array region of the memory die corresponding to the heating block.

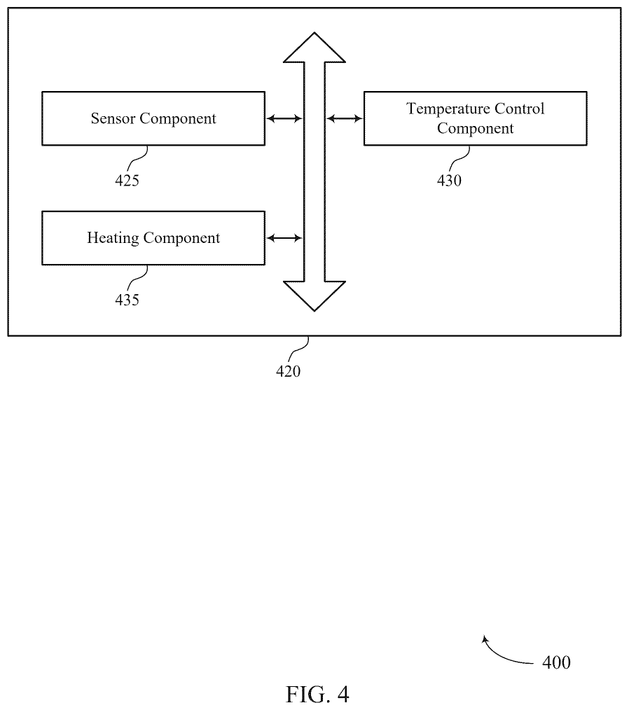

FIG. 4 shows a block diagram 400 of a system 420 that supports on-die heating for a memory device in accordance with examples as disclosed herein. The system 420 may be an example of aspects of a memory system as described with reference to FIG. 1 and a system as described with reference to FIG. 2A. The system 420, or various components thereof, may be an example of means for performing various aspects of on-die heating for a memory device as described herein. For example, the system 420 may include a sensor component 425, a temperature control component 430, a heating component 435, or any combination thereof. Each of these components, or components of subcomponents thereof (e.g., one or more processors, one or more memories), may communicate, directly or indirectly, with one another (e.g., via one or more buses).

The sensor component 425 may be configured as or otherwise support a means for monitoring a temperature associated with a memory die that includes a set of heating blocks that can heat the memory die. The temperature control component 430 may be configured as or otherwise support a means for generating an activation signal based at least in part on the temperature associated with the memory die satisfying one or more thresholds. The heating component 435 may be configured as or otherwise support a means for activating one or more heating blocks of the set of heating blocks based at least in part on the activation signal, the activating adjusting the temperature associated with the memory die.

In some examples, the temperature control component 430 may be configured as or otherwise support a means for selecting a heating level from a set of heating levels corresponding to the set of heating blocks based at least in part on the temperature satisfying the one or more thresholds.

In some examples, the activation signal is based at least in part on the selected heating level. In some examples, activating the one or more heating blocks is based at least in part on the selected heating level.

In some examples, to support selecting the heating level, the temperature control component 430 may be configured as or otherwise support a means for selecting a first heating level from the set of heating levels based at least in part on the temperature being equal to or greater than a first threshold. In some examples, to support selecting the heating level, the temperature control component 430 may be configured as or otherwise support a means for selecting a second heating level from the set of heating levels based at least in part on the temperature being equal to, less than, or greater than a second threshold that is less than the first threshold. In some examples, to support selecting the heating level, the temperature control component 430 may be configured as or otherwise support a means for selecting a third heating level from the set of heating levels based at least in part on the temperature being equal to or less than a third threshold that is less than the second threshold.

In some examples, to support generating the activation signal, the temperature control component 430 may be configured as or otherwise support a means for generating the activation signal based at least in part on the temperature being equal to or less than a threshold of the one or more thresholds.

In some examples, the temperature control component 430 may be configured as or otherwise support a means for generating a deactivation signal based at least in part on the temperature increasing above the threshold of the one or more thresholds. In some examples, the temperature control component 430 may be configured as or otherwise support a means for deactivating the one or more heating blocks of the set of heating blocks based at least in part on the deactivation signal.

In some examples, the temperature control component 430 may be configured as or otherwise support a means for selecting the one or more heating blocks from the set of heating blocks based at least in part on the temperature satisfying the one or more thresholds. In some examples, the temperature control component 430 may be configured as or otherwise support a means for generating a second activation signal including an indication to enable the one or more heating blocks based at least in part on the selecting.

In some examples, each heating block of the set of heating blocks includes a first transistor coupled with ground and a second transistor coupled with a voltage source and the first transistor.

In some examples, to support activating each heating block of the set of heating blocks, the heating component 435 may be configured as or otherwise support a means for applying a first voltage to a first gate of the first transistor of the heating block to switch the first transistor to an on state. In some examples, to support activating each heating block of the set of heating blocks, the heating component 435 may be configured as or otherwise support a means for applying a second voltage to a second gate of the second transistor of the heating block to switch the second transistor to the on state.

In some examples, the described functionality of the system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the system 420, or various components thereof, may be implemented at least in part by instructions (e.g., stored in memory, non-transitory computer-readable medium) executable by such at least one processor.

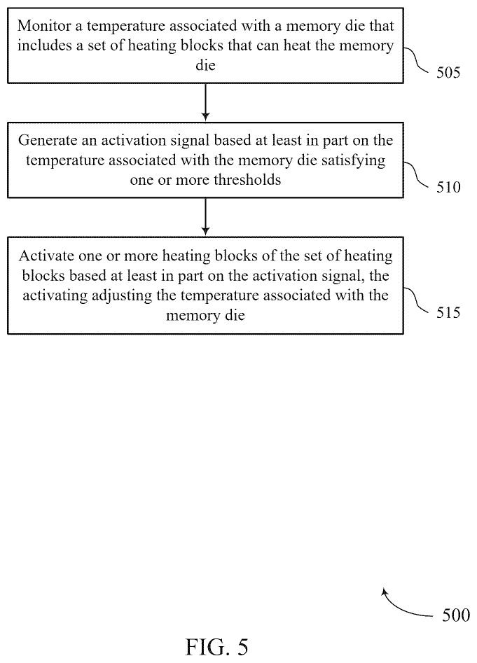

FIG. 5 shows a flowchart illustrating a method 500 that supports on-die heating for a memory device in accordance with examples as disclosed herein. The operations of method 500 may be implemented by a system or its components as described herein. For example, the operations of method 500 may be performed by a system as described with reference to FIGS. 1 and 2A. In some examples, a system may execute a set of instructions to control the functional elements of the device to perform the described functions. Additionally, or alternatively, the system may perform aspects of the described functions using special-purpose hardware.

At 505, the method may include monitoring a temperature associated with a memory die that includes a set of heating blocks that can heat the memory die. In some examples, aspects of the operations of 505 may be performed by a sensor component 425 as described with reference to FIG. 4.

At 510, the method may include generating an activation signal based at least in part on the temperature associated with the memory die satisfying one or more thresholds. In some examples, aspects of the operations of 510 may be performed by a temperature control component 430 as described with reference to FIG. 4.

At 515, the method may include activating one or more heating blocks of the set of heating blocks based at least in part on the activation signal, the activating adjusting the temperature associated with the memory die. In some examples, aspects of the operations of 515 may be performed by a heating component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for monitoring a temperature associated with a memory die that includes a set of heating blocks that can heat the memory die; generating an activation signal based at least in part on the temperature associated with the memory die satisfying one or more thresholds; and activating one or more heating blocks of the set of heating blocks based at least in part on the activation signal, the activating adjusting the temperature associated with the memory die.

Aspect 2: The method, apparatus, or non-transitory computer-readable medium of aspect 1, further including operations, features, circuitry, logic, means, or instructions, or any combination thereof for selecting a heating level from a set of heating levels corresponding to the set of heating blocks based at least in part on the temperature satisfying the one or more thresholds.

Aspect 3: The method, apparatus, or non-transitory computer-readable medium of aspect 2, where the activation signal is based at least in part on the selected heating level and activating the one or more heating blocks is based at least in part on the selected heating level.

Aspect 4: The method, apparatus, or non-transitory computer-readable medium of any of aspects 2 through 3, where selecting the heating level includes operations, features, circuitry, logic, means, or instructions, or any combination thereof for selecting a first heating level from the set of heating levels based at least in part on the temperature being equal to or greater than a first threshold; selecting a second heating level from the set of heating levels based at least in part on the temperature being equal to, less than, or greater than a second threshold that is less than the first threshold; and selecting a third heating level from the set of heating levels based at least in part on the temperature being equal to or less than a third threshold that is less than the second threshold.

Aspect 5: The method, apparatus, or non-transitory computer-readable medium of any of aspects 1 through 4, where generating the activation signal includes operations, features, circuitry, logic, means, or instructions, or any combination thereof for generating the activation signal based at least in part on the temperature being equal to or less than a threshold of the one or more thresholds.

Aspect 6: The method, apparatus, or non-transitory computer-readable medium of aspect 5, further including operations, features, circuitry, logic, means, or instructions, or any combination thereof for generating a deactivation signal based at least in part on the temperature increasing above the threshold of the one or more thresholds and deactivating the one or more heating blocks of the set of heating blocks based at least in part on the deactivation signal.

Aspect 7: The method, apparatus, or non-transitory computer-readable medium of any of aspects 1 through 6, further including operations, features, circuitry, logic, means, or instructions, or any combination thereof for selecting the one or more heating blocks from the set of heating blocks based at least in part on the temperature satisfying the one or more thresholds and generating a second activation signal including an indication to enable the one or more heating blocks based at least in part on the selecting.

Aspect 8: The method, apparatus, or non-transitory computer-readable medium of any of aspects 1 through 7, where each heating block of the set of heating blocks includes a first transistor coupled with ground and a second transistor coupled with a voltage source and the first transistor.

Aspect 9: The method, apparatus, or non-transitory computer-readable medium of aspect 8, where activating each heating block of the set of heating blocks includes operations, features, circuitry, logic, means, or instructions, or any combination thereof for applying a first voltage to a first gate of the first transistor of the heating block to switch the first transistor to an on state and applying a second voltage to a second gate of the second transistor of the heating block to switch the second transistor to the on state.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: A system, including: a memory die including a plurality of array regions; a temperature sensor configured to sense a temperature associated with the memory die; one or more controllers coupled with the temperature sensor and configured to generate an activation signal based at least in part on the temperature associated with the memory die satisfying one or more thresholds; and a heater located on the memory die and coupled with the one or more controllers, the heater configured to dissipate heat to one or more array regions of the plurality of array regions based at least in part on the activation signal, where the heater includes a set of heating blocks each associated with a respective array region of the plurality of array regions.

Aspect 11: The system of aspect 10, where each heating block of the set of heating blocks includes one or more transistors configured to generate at least a portion of the heat.

Aspect 12: The system of aspect 11, where the one or more transistors include: a first transistor coupled with ground; and a second transistor coupled with a voltage source and the first transistor, where the one or more controllers are coupled with a first gate of the first transistor and a second gate of the second transistor.

Aspect 13: The system of aspect 12, where the one or more transistors include one or more of a PMOS transistor or a NMOS transistor.

Aspect 14: The system of claim 11, where the one or more transistors are configured to: switch to an on state based at least in part on the activation signal; and generate at least a portion of the heat based at least in part on switching to the on state and a current through the one or more transistors.

Aspect 15: The system of any of aspects 10 through 14, where the one or more controllers are further configured to select a heating level from a set of heating levels corresponding to the set of heating blocks based at least in part on the temperature satisfying the one or more thresholds.

Aspect 16: The system of aspect 15, where the activation signal is based at least in part on the selected heating level.

Aspect 17: The system of any of aspects 15 through 16, where, to select the heating level, the one or more controllers are configured to: select a first heating level from the set of heating levels based at least in part on the temperature being equal to or greater than a first threshold; or select a second heating level from the set of heating levels based at least in part on the temperature being equal to, less than, or greater than a second threshold that is less than the first threshold; or select a third heating level from the set of heating levels based at least in part on the temperature being equal to or less than a third threshold that is less than the second threshold.

Aspect 18: The system of any of aspects 10 through 17, where, to generate the activation signal, the one or more controllers are configured to: generate the activation signal based at least in part on the temperature being equal to or less than a threshold of the one or more thresholds.

Aspect 19: The system of aspect 18, where the one or more controllers are further configured to generate a deactivation signal for deactivation of the heater based at least in part on the temperature increasing above the threshold of the one or more thresholds.

Aspect 20: The system of any of aspects 10 through 19, where the one or more controllers are further configured to: select a subset of heating blocks from the set of heating blocks based at least in part on the temperature satisfying the one or more thresholds; and generate a second activation signal including an indication to enable the subset of heating blocks based at least in part on the selection, where the heater is configured to dissipate heat from the subset of heating blocks based at least in part on the second activation signal.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A system, comprising:
a memory die comprising a plurality of array regions;
a temperature sensor configured to sense a temperature associated with the memory die;
one or more controllers coupled with the temperature sensor and configured to generate an activation signal based at least in part on the temperature associated with the memory die satisfying one or more thresholds; and
a heater located on the memory die and coupled with the one or more controllers, the heater configured to dissipate heat to one or more array regions of the plurality of array regions based at least in part on the activation signal, wherein the heater comprises a set of heating blocks each associated with a respective array region of the plurality of array regions.

2. The system of claim 1, wherein each heating block of the set of heating blocks comprises one or more transistors configured to generate at least a portion of the heat.

3. The system of claim 2, wherein the one or more transistors comprise:
a first transistor coupled with ground; and
a second transistor coupled with a voltage source and the first transistor, wherein the one or more controllers are coupled with a first gate of the first transistor and a second gate of the second transistor.

4. The system of claim 3, wherein the one or more transistors comprise one or more of a positive metal-oxide semiconductor transistor or a negative metal-oxide semiconductor transistor.

5. The system of claim 2, wherein the one or more transistors are configured to:
switch to an on state based at least in part on the activation signal; and
generate at least a portion of the heat based at least in part on switching to the on state and a current through the one or more transistors.

6. The system of claim 1, wherein the one or more controllers are further configured to select a heating level from a set of heating levels corresponding to the set of heating blocks based at least in part on the temperature satisfying the one or more thresholds.

7. The system of claim 6, wherein the activation signal is based at least in part on the selected heating level.

8. The system of claim 6, wherein, to select the heating level, the one or more controllers are configured to:
select a first heating level from the set of heating levels based at least in part on the temperature being equal to or greater than a first threshold;
select a second heating level from the set of heating levels based at least in part on the temperature being equal to, less than, or greater than a second threshold that is less than the first threshold; or
select a third heating level from the set of heating levels based at least in part on the temperature being equal to or less than a third threshold that is less than the second threshold.

9. The system of claim 1, wherein, to generate the activation signal, the one or more controllers are configured to:
generate the activation signal based at least in part on the temperature being equal to or less than a threshold of the one or more thresholds.

10. The system of claim 9, wherein the one or more controllers are further configured to generate a deactivation signal for deactivation of the heater based at least in part on the temperature increasing above the threshold of the one or more thresholds.

11. The system of claim 1, wherein the one or more controllers are further configured to:
select a subset of heating blocks from the set of heating blocks based at least in part on the temperature satisfying the one or more thresholds; and
generate a second activation signal comprising an indication to enable the subset of heating blocks based at least in part on the selection, wherein the heater is configured to dissipate heat from the subset of heating blocks based at least in part on the second activation signal.

12. A method, comprising:
monitoring a temperature associated with a memory die that comprises a set of heating blocks that can heat the memory die;
generating an activation signal based at least in part on the temperature associated with the memory die satisfying one or more thresholds; and
activating one or more heating blocks of the set of heating blocks based at least in part on the activation signal, the activating adjusting the temperature associated with the memory die.

13. The method of claim 12, further comprising:
selecting a heating level from a set of heating levels corresponding to the set of heating blocks based at least in part on the temperature satisfying the one or more thresholds.

14. The method of claim 13, wherein the activation signal is based at least in part on the selected heating level, and activating the one or more heating blocks is based at least in part on the selected heating level.

15. The method of claim 13, wherein selecting the heating level comprises:
selecting a first heating level from the set of heating levels based at least in part on the temperature being equal to or greater than a first threshold;
selecting a second heating level from the set of heating levels based at least in part on the temperature being equal to, less than, or greater than a second threshold that is less than the first threshold; or
selecting a third heating level from the set of heating levels based at least in part on the temperature being equal to or less than a third threshold that is less than the second threshold.

16. The method of claim 12, wherein generating the activation signal comprises:
generating the activation signal based at least in part on the temperature being equal to or less than a threshold of the one or more thresholds.

17. The method of claim 16, further comprising:
generating a deactivation signal based at least in part on the temperature increasing above the threshold of the one or more thresholds; and
deactivating the one or more heating blocks of the set of heating blocks based at least in part on the deactivation signal.

18. The method of claim 12, further comprising:
selecting the one or more heating blocks from the set of heating blocks based at least in part on the temperature satisfying the one or more thresholds; and
generating a second activation signal comprising an indication to enable the one or more heating blocks based at least in part on the selecting.

19. The method of claim 12, wherein each heating block of the set of heating blocks comprises a first transistor coupled with ground and a second transistor coupled with a voltage source and the first transistor.

20. The method of claim 19, wherein activating each heating block of the set of heating blocks comprises:
applying a first voltage to a first gate of the first transistor of the heating block to switch the first transistor to an on state; and
applying a second voltage to a second gate of the second transistor of the heating block to switch the second transistor to the on state.

21. An apparatus, comprising:
processing circuitry associated with one or more memory dice and configured to cause the apparatus to:
monitor a temperature associated with a memory die that comprises a set of heating blocks that can heat the memory die;
generate an activation signal based at least in part on the temperature associated with the memory die satisfying one or more thresholds; and
activate one or more heating blocks of the set of heating blocks based at least in part on the activation signal, the activating adjusting the temperature associated with the memory die.

22. The apparatus of claim 21, wherein the processing circuitry is further configured to cause the apparatus to:
select a heating level from a set of heating levels corresponding to the set of heating blocks based at least in part on the temperature satisfying the one or more thresholds.
